(19) United States
(12) Patent Application Publication
(10) Pub. No.: US 2022/0027584 A1
(43) Pub. Date: Jan. 27, 2022

(54) METHOD FOR READING OUT DEVICE PARAMETERS OF AN ELECTRICAL UNIT AND A CORRESPONDING ELECTRICAL UNIT

(71) Applicant: TURCK Holding GmbH, Halver (DE)

(72) Inventors: Hermann Schwagmann, Detmold (DE); Thomas Kriegel, Luedenscheid (DE)

(21) Appl. No.: 17/382,369

(22) Filed: Jul. 22, 2021

(30) Foreign Application Priority Data
Jul. 22, 2020 (DE) 10 2020 119 359.9
Jul. 8, 2021 (DE) 10 2021 117 624.7

(51) Int. Cl. G06K 7/10; G06K 19/07

(52) U.S. Cl. CPC G06K 7/10366; G06K 7/10297; G06K 19/0723

(57) ABSTRACT

An electrical unit has a microcontroller-based electronic circuit. The electrical unit includes a memory module connected to a microcontroller of the microcontroller-based electronic circuit and configured to store data during operation of the electrical unit. The electrical unit further includes a wireless interface via which the data can be read out from the memory module.

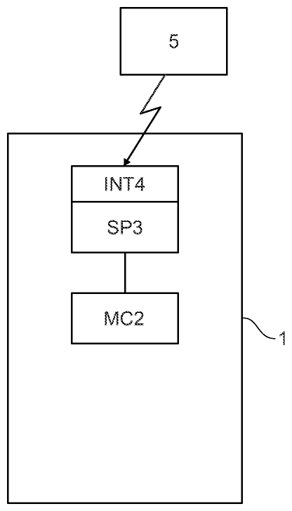

### CROSS-REFERENCE TO PRIOR APPLICATIONS

This application claims benefit to German Patent Application Nos. DE 10 2020 119 359.9, filed on Jul. 22, 2020, and DE 10 2021 117 624.7, filed on Jul. 8, 2021, which are hereby incorporated by reference herein.

### FIELD

The present disclosure relates to a method for reading out device parameters of an electrical unit and to a corresponding electrical unit.

### BACKGROUND

Configuration data stored in field devices are advantageously taken over for the new device when a field device is replaced. For this purpose, DE 10 2011 089 346 A1 describes a method for operating a field device in process automation technology so as to provide the basic function of the field device even if the energy supply of the field device, for example by means of the field bus, were to fail.

In the event of a total failure of the field device or of another electrical unit, however, it can be time-consuming to retrospectively find the fault that caused the failure. The faults may have been, for example, environmental influences (vibrations, fire, pressure, etc.) or operational faults (interruption of an update).

Microcontroller-based electronic circuits, as used in electrical units, for example in a field bus station having communications interfaces and inputs/outputs, in a sensor unit or in infrastructure components such as switches, are exposed to many damaging environmental conditions and/or can be destroyed by incorrect operation. These electronic circuits are protected against such environmental and usage conditions by suitable measures. These include mechanical and structural solutions, such as housings, seals, potting, paints and encapsulation with plastics, which enclose these circuits and protect them against mechanical influences (shocks, vibrations) and prevent the entry of water or other damaging materials. Technical solutions that can prevent, for example, destructive voltage peaks, overloading, overheating or incorrect use or usage within particular limits are also used. All stresses that can occur beyond that destroy the electronic circuit or its components in the short or long term. Normally, the user of the device is made aware of these by means of instruction manuals and information in standards, so as to ensure that these electronic circuits are not used beyond the stated load limits or destroyed as a result of any other incorrect use. For example, incorrect use could be excessive ambient temperature, operation under water, excessive current or voltage load, or vibrational stresses. A further source of faults is when the energy supply is interrupted during critical operational statuses of a device, for example when it is undergoing a software update.

Despite all the protective measures and instructions and operating restrictions, electronic circuits and devices are still destroyed. Once these circuits or devices have been destroyed, they are no longer fit for operation, for the avoidance of doubt.

### SUMMARY

In an embodiment, the present disclosure provides an electrical unit having a microcontroller-based electronic circuit. The electrical unit includes a memory module connected to a microcontroller of the microcontroller-based electronic circuit and configured to store data during operation of the electrical unit. The electrical unit further includes a wireless interface via which the data can be read out from the memory module.

### BRIEF DESCRIPTION OF THE DRAWINGS

Subject matter of the present disclosure will be described in even greater detail below based on the exemplary FIGURES. All features described and/or illustrated herein can be used alone or combined in different combinations. The features and advantages of various embodiments will become apparent by reading the following detailed description with reference to the attached drawings, which illustrate the following:

The FIGURE shows a schematic view of an electrical unit having a microcontroller-based circuit.

### DETAILED DESCRIPTION

The present disclosure provides an electrical unit in which it is simpler to find the fault in the event of a total failure, and provides a method for reading out device parameters, operation data or operational statuses of an electrical unit that can be carried out in the event of a total failure of the electrical unit.

The present disclosure provides an electrical unit having a microcontroller-based electronic circuit, comprising a memory module that is connected to the microcontroller and configured to store data during operation of the electrical unit, wherein a wireless interface is provided via which the data can be read out from the memory module.

The electrical unit can be formed in various ways. In particular, it comprises an electronic component, for instance a network or control component, an input and/or output interface, as well as optionally other electronic elements.

In an embodiment, the electrical unit is formed as a field device or as an electrical plug connector.

A field device can be, for instance, a field bus station having communications interfaces and inputs/outputs, a sensor unit or an infrastructure component such as a switch. A field device can be formed such that it is directly related to a production process, for instance a production plant. The field device can in particular be formed as an actuator and/or sensor.

Furthermore, as electrical unit, an electrical plug connector can be provided, which can be formed in various ways and is not limited to connectors which can be connected merely by plugging. Rather, other connectors can also be included, in which input-side contacts can be connected to a complementary plug at least partially through a plugging process. Such a plug connector is suitable for instance for connecting cables and further devices. For this purpose, it is preferably provided with input-side and output-side contacts.

The electrical plug connector is suitable, for example, for transmitting electrical energy and/or data.

An electrical plug connector can comprise an electronic device, in particular an electronic circuit. This circuit is preferably arranged inside a housing of the electrical plug connector.

For example, the plug connector can have a sensor device, by means of which an electrical operating parameter and/or an environmental parameter can be recorded.

A recordable operating parameter can be, for example, a value which is assigned to the plug connector and/or to a cable connected to it or a wire and/or to a further connected unit. In particular, the operating parameter is chosen such that it represents a characteristic of a power and/or data transmission.

The operating parameter can be various variables, for example voltage and/or current. Furthermore, other variables can be recorded as operating parameters, for instance a capacitance, inductance, resistance, impedance, frequency, a thermal property and/or further wire characteristics. A field strength can be recorded, for example, by means of a Hall sensor.

The recording is effected in particular in a manner known per se, for instance by a sensor element for measuring an amperage or a voltage. The operating parameter can be recorded, for example, between input-side and output-side contacts, for instance by a series-connected sensor element of the sensor device. The measurement can be effected in the case of a connection which exists between an input-side contact and an output-side contact. Furthermore, a recording of the electrical operating parameter can be effected between different connections which exist in each case between input-side and output-side contacts assigned to the connection. For example, potential differences between two electrical wires which are connected to the plug connector can be measured thereby.

For example, input and/or output voltages can be determined, for instance via the measurement of an amperage, and thus a voltage difference between plug connectors can be calculated. In particular, a voltage drop is recorded in this way. Furthermore, a cable temperature can be recorded, which can represent an indication of, for example, the temperature-dependent electrical resistance of the connection. Furthermore, a status monitoring for a connected cable can be implemented, for instance in order to identify a damaged cable.

For example, a microcontroller and/or a memory unit and/or a power supply circuit can be integrated directly into the plug connector.

A recordable environmental parameter can relate to different properties of a spatial environment of the electrical unit, for instance a temperature, moisture, pressure, vibrations, speed or acceleration.

A sensor unit of the electrical plug connector can additionally be configured to record a transmitted data volume and/or a transmission rate.

The electrical unit can furthermore be formed differently, for instance as a device which is actuatable in a different way from a field bus or which functions without external actuation.

The electrical unit can furthermore comprise an RFID read/write head or be formed as one; such a unit can in turn be formed as a field device or sensor.

The electrical unit can furthermore be formed as a device for recording and storing data, for instance as a stand-alone data logger; for example, the electrical unit can be configured to record and/or log an environmental parameter, such as for instance a temperature, humidity or vibrations. In the event of damage to the electrical unit, for instance to a data logger due to extreme conditions, the data can then still be readable.

The electrical unit can furthermore comprise a mobile terminal or be formed as one, for instance a handheld unit for recording and/or outputting data.

The electrical unit can furthermore be formed as a device which a user wears on their body or clothes, in particular so-called “wearables”.

In particular, semiconductor chips containing a processor and also peripheral functions at the same time are referred to as microcontrollers (also called μController, μC, MCU). In many cases, the working and program memory is also located on the same chip either in part or in full. A microcontroller is a single-chip computer system. The term “system on a chip” or “SoC” is also used for some microcontrollers. Preferably, complex peripheral functions are also found on microcontrollers, such as, for example, controller area network (CAN) interfaces, local interconnect network (LIN) interfaces, universal serial bus (USB) interfaces, inter-integrated circuit (I2C) interfaces, serial peripheral interfaces (SPI), serial or ethernet interfaces, PWM outputs, LCD controllers and drivers, and A/D converters. Preferably, microcontrollers also have programmable digital and/or analogue or hybrid functional blocks.

The memory module is preferably a separate memory module designed separate from the microcontroller and merely connected to the microcontroller. It is also possible for the memory module to be constructed together with the microcontroller and for the memory module to be located on the same chip as the microcontroller. The memory module can also be integrated in a tag of the wireless interface, in particular in an RFID/NFC tag. The memory module can have a first interface, by which it can be connected to the microcontroller, and a second interface, which is wireless and via which it can be read out and preferably also written to.

The memory module is configured to store data or information during operation of the electrical unit. These data or information can contain valuable application information (device configuration, programs, usage information, etc.) or other operational information, such as the number of overloads detected during operation, and/or measured environmental values such as temperature or moisture, operating hours, or the latest status information, such as “Currently undergoing system software update”, “Voltage peak detected”, “Ambient temperature too high” etc. For this purpose, the memory module is preferably connected to the microcontroller in an electrically conductive manner, particularly preferably likewise via a wireless interface.

The wireless interface via which the data can be read out from the memory module is preferably in the form of a distinct component and is connected to the memory. Via this interface, it is possible to read out the data in the memory module even when the microcontroller is no longer addressable. Particularly preferably, the wireless interface via which the data can be read out from the memory module is formed integral with the memory.

By adding a memory module that is connected to the microcontroller and preferably also addressable as a passive NFC tag to a microcontroller-based electronic circuit of this kind in an electrical unit, the data that have been stored on the memory module during operation can be read out independently of the status of the rest of the components and, by means of an evaluation, it can be determined what led to the (total) failure of the field device. Information that was stored on this memory module can thus be read out “post mortem”. Thus it is possible to still obtain information about a circuit (or device) that is otherwise no longer fit for operation, for example by bringing an RFID reader close to the outside of it.

Often, memory modules can also be released from the destroyed circuits and inserted or addressed in functioning electronic circuits or systems. As a result, the valuable information is available again. However, this is more complex than reading out the data via the wireless interface, in particular when the modules are, for example, potted or painted or otherwise not easily accessible in technical terms and thus cannot be removed in a destruction-free manner—potentially only by heat-treatment or release with chemicals. Electronic circuits and devices can thus be analyzed “post mortem” despite no longer being able to be started up. Related findings can serve as evidence of incorrect handling and can avoid warranty or damages claims, or provide valuable information on the status of the device in order to make it simpler to remedy faults for a device type.

In an advantageous electrical unit, the memory module is configured to be addressable as a passive RFID tag. A memory module that is connected to the microcontroller and also addressable as a passive RFID tag is thus added to a microcontroller-based electronic circuit of this kind. It is also possible to use an HF RFID tag or an NFC tag. Preferably, a combination of several tags is used to increase redundancy. In this case, the tags can be several identical tags or several tags of different designs, i.e. RFID tags, HF RFID tags or NFC tags in combination, or tags of different storage capacities in combination. This also makes it possible to store different content on the different memories of the individual tags and thus to retrieve it again by means of different tags and their wireless interfaces.

By means of this RFID tag, information can be read out via the wireless interface even before the device is damaged, and preferably it is also possible to write information to the memory module of the tag via the wireless interface. As a result, maintenance or inspection data, for example, can be stored on the memory module or older data can also be deleted.

Tags having an interface to the microcontroller in addition to the wireless interface are preferably used. The RFID tag having the memory module is thus the data medium for the logged data.

Further preferably, an electrical unit is provided in which the memory module has a transponder, preferably in accordance with the NFC and/or RFID standard.

Near field communication (NFC) is an international transmission standard based on RFID technology for contactlessly exchanging data by electromagnetic induction by means of loose coupled coils over short distances of a few centimetres and at a maximum data transmission rate of 424 kBit/s.

Radio-frequency identification (RFID) denotes a technology for transceiver systems to automatically and contactlessly identify and locate objects and living things using radio waves.

Generally, an RFID system consists of a transponder (also referred to colloquially as a radio tag), which is located on or in the object, thus in this case preferably the memory module, and contains a characteristic code, and of a reader for reading out this identifier.

It is possible to produce RFID transponders from polymers by means of a special printing process for stable circuits.

The coupling is preferably established either by short-range magnetic alternating fields generated by the reader or by high-frequency radio waves. As a result, preferably not only are data transmitted, but the transponder is supplied with energy too.

The reader preferably contains software (a microprogram) that controls the actual reading process, and particularly preferably also RFID middleware having interfaces to further electronic data processing systems and databases.

Further preferably, an electrical unit is provided in which the memory module and/or the microcontroller is/are installed so as to be inaccessible in technical terms. The modules can thus be protected against environmental influences and damage.

Further preferably, an electrical unit is provided in which the data include station parameters of the device or other operating parameters.

In this context, station parameters preferably comprise necessary configuration data, e.g. device parameters, but also production data.

Operating parameters preferably comprise everything recorded by the microcontroller and loaded into the memory in addition to the station parameters regarding the operating time, e.g. (working) voltage values, reasons for resets, bootloader mode and/or other significant memory content. Data on temperature, vibrations, radiation, operating time fault codes, statuses and communications parameters can also be recorded. The status can comprise the ongoing exchange of process data, the configuration mode, the start-up phase and data rates in the network. For the working voltage, the charging status of the accumulator or battery can be recorded in particular.

TheA method for reading out device parameters of an electrical unit is also provided, wherein data on the operating time of the electrical unit have been stored in a memory module and the electrical unit then has a malfunction in which the electrical unit cannot communicate by means of wired channels, the microcontroller or the processing unit of the electrical unit is no longer addressable and the electrical unit is not connected to a power supply. The method includes reading out the data from the memory module via the wireless interface.

Further preferably, a method is provided that further comprises the step of: reading out the data from the memory module via the wireless interface by means of RFID or NFC.

Further preferably, a method is provided that further comprises the step of: displaying the read-out data on a mobile terminal. A portable computer, a smartphone or a reader can be used as the mobile terminal.

Further preferably, a method is provided that further comprises the step of: interpreting the read-out data on the basis of a predefined evaluation mapping.

Preferably, this evaluation mapping is structured in a database. The database can preferably be called up in a location-independent manner, in particular via the internet or web access. Preferably, the database is configured to be centrally supplemented with product-related fault codes or status codes. The database is preferably configured such that corresponding fault codes or status codes can be output in text form (human-readable and interpretable) by means of identifying features of the product (product name, ID, batch number).

The FIGURE shows a schematic view of an electrical unit (1), which is formed as a field device (1) in the embodiment example, having a microcontroller-based circuit, comprising a microcontroller (MC2) and a memory module (SP3) connected thereto. A wireless interface (INT4) is also provided.

During operation, data are written to the memory module (SP3) by the microcontroller (MC2).

The data are transmitted to a mobile terminal (5) via the wireless interface (INT4).

Preferably, the memory module (SP3) and the wireless interface are an RFID tag. This RFID tag is connected to the microcontroller (MC2) and is configured to store the data made available by the microcontroller (MC2). The data can be data such as statuses, for example that an update is currently being loaded and installed, or environmental parameters such as temperature, vibrations or moisture.

If the electrical unit (1) now fails and the microcontroller (MC2) is no longer addressable, a mobile terminal (5), for example a laptop or a smartphone, can be used to read out the content of the memory module (SP3), i.e. of the RFID tag, via the interface (INT4). The data obtained therefrom can then be displayed on the mobile terminal (5) and visualized by interpreting the read-out data on the basis of a predefined evaluation mapping. The data can thus be evaluated, and it can be displayed to the operator of the mobile terminal (5) on a display that an update has been installed, during the process of which vibrations increased and shortly after that the working voltage dropped out.

By means of the electrical unit and the method for reading out parameters from that electrical unit, it is possible to establish, even after damage has occurred, which circumstances caused the device to fail since these data can be read out “post mortem” via the wireless interface without any need for a complex analysis and mechanical release of parts, which, for example, may have been potted in.

In a further embodiment example, the electrical unit (1) is formed differently, for instance as an electrical plug connector. The mode of operation is in principle the same as described above for a field device (1).

In an embodiment example, the electrical unit (1), for instance an electrical plug connector, comprises a sensor element. The sensor element is formed to record operating and environmental parameters in this embodiment example. During operation of the electrical unit (1), parameters such as an ambient temperature, a transmitted voltage, current or power, a data transmission rate or a field strength are measured and written to the memory module (SP3).

For example, a recorded value of a parameter can then be written to the memory module (SP3) when a predefined threshold value is exceeded or not reached, or when other conditions are met.

In further embodiments of the electrical unit, a replacement electrical unit can additionally be parameterized by means of the data that can be read out via the wireless interface, with the result that it can then take over the role of the damaged unit in a timely manner.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS

1 Electronic unit; field device
2 Microcontroller MC2
3 Memory module SP3
4 Wireless interface INT4
5 Data mobile terminal

1. An electrical unit having a microcontroller-based electronic circuit, the electrical unit comprising:
a memory module connected to a microcontroller of the microcontroller-based electronic circuit and configured to store data during operation of the electrical unit; and
a wireless interface via which the data can be read out from the memory module.

2. The electrical unit according to claim 1, wherein the electrical unit is formed as a field device or as an electrical plug connector.

3. The electrical unit according to claim 1, wherein the separate memory module is configured to be addressable as a passive RFID tag.

4. The electrical unit according to claim 1, wherein the memory module has a transponder.

5. The electrical unit according to claim 1, wherein the memory module and/or the microcontroller is/are installed so as to be inaccessible in technical terms.

6. The electrical unit according to claim 1, wherein the data comprise station parameters of the device or other operating parameters.

7. A method for reading out device parameters of an electrical unit, the method comprising:
storing data on an operating time of the electrical unit in a memory module;
reading out, after the electrical unit has a malfunction after which the electrical unit cannot communicate via wired channels and the microcontroller of the electrical unit is no longer addressable and the electrical unit is not connected to a power supply, the data from the memory module via the wireless interface.

8. The method according to claim 7, further comprising the step of: reading out the data from the memory module via the wireless interface via RFID or NFC.

9. The method according to claim 7, further comprising displaying the read-out data on a mobile terminal.

10. The method according to claim 7, further comprising interpreting the read-out data on the basis of a predefined evaluation mapping.
